(19) United States
(12) Patent Application Publication
(10) Pub. No.: US 2020/0116757 A1
(43) Pub. Date: Apr. 16, 2020

(54) CONTACT MODULE FOR MAKING ELECTRICAL TACTILE CONTACT WITH A COMPONENT, AND CONTACT SYSTEM

(71) Applicant: FEINMETALL GMBH, Herrenberg (DE)

(72) Inventors: Lutz BENEDIX, Herrenberg (DE); Jörg BURGOLD, Herrenberg (DE); Gerhard KUGEL, Ebhausen (DE); Jan SCHITTENHELM, Herrenberg (DE); Ulrich LIEB, Obersulm (DE)

(73) Assignee: FEINMETALL GMBH, Herrenberg (DE)

(21) Appl. No.: 16/617,281

(22) PCT Filed: May 30, 2018
(86) PCT No.: PCT/EP2018/064316

§ 371 Date: Nov. 26, 2019

(30) Foreign Application Priority Data
Jun. 2, 2017 (DE) 10 2017 209 443.5

(51) Int. Cl. G01R 1/067; G01R 1/073; G01R 1/04

(52) U.S. Cl. CPC G01R 1/06722; G01R 1/0408; G01R 1/073

(57) ABSTRACT

A contact module for making electrical tactile contact with a component includes a carrier having a contact side assignable to the component and a connection side facing away from the contact side, with at least two electrically conductive contact elements, of which at least one is a spring contact pin with a spring-loaded contact head, wherein free ends of the contact elements protrude from the contact side of the carrier for the purpose of making tactile contact with the component. At least one protective wall is disposed on the contact side of the carrier, the wall forming at least one contact space in which the free ends of the contact elements are disposed.

The invention relates to a contact module for making electrical tactile contact with an electrical component, in particular an energy storage medium, having a carrier which has a contact side that can be assigned to the component and a connection side facing away from the contact side, and at least two electrically conductive contact elements, at least one of which is a spring contact pin, wherein free ends of the contact elements protrude from the contact side of the carrier for the purpose of making tactile contact with the component.

The invention further relates to a contact system for making electrical tactile contact with a plurality of components, which is in particular identically designed, in particular energy storage media, the system comprising at least one carrier system plate having a plurality of openings, in particular evenly spaced openings, and with a plurality of contact modules for making electrical tactile contact with the components, wherein one of the contact modules is in particular releasably locked or lockable in each of the one or more openings.

Contact modules and contact systems of such type mentioned are already known from the prior art. Thus, for example, the utility model DE 20 2013 000 140 U1 discloses a contact module with a carrier to which a plurality of spring contact pins is attached as contact elements. The spring contact pins protrude from the contact side of the contact module, so that contact heads of the spring contact pins can be compressed in the direction of the carrier during tactile contact. The spring contact pins thus ensure that each individual contact of the component can be reliably contacted in that height differences of the contact points of the component can be compensated by the spring-loaded contact heads. Such contact modules are used, for example, to test the functionality of electrical components, such as circuit boards, wafers, circuits or energy storage media. In addition, such contact modules are used to apply an electrical voltage or an electric current to electrical energy storage media for the purposes of forming the energy cells of the energy storage medium.

It is also known to provide contact systems in which one or more contact modules can be arranged on a carrier system plate in order to enable tactile contacting or testing and/or processing of a plurality of in particular identically designed components by simultaneously moving all contact modules by means of the carrier system plate, so that time expenditure and efficiency of the system are optimized.

The object of the invention is to provide a contact module and a contact system, which allow, in a simple and cost-effective manner, secure tactile contacting of components and in particular the electrical contact points of components, in particular of electrical energy storage media.

The object of the invention is achieved by a contact module with the features of claim 1. This has the advantage that on the one hand, the assignment of the component to the contact elements of the contact module is mechanically simplified, and that on the other hand in a contacting process, it is ensured that no unwanted electrical connections occur which, for example, lead to a short circuit between adjacent contact elements or the contact elements of adjacent contact modules, and that the contact elements are also protected from external influences when not in use. According to the invention, this is achieved by arranging at least one protective wall on the contact side of the carrier, the wall forming a contact space in which the free ends of the contact elements are disposed. The protective wall ensures that, for example, no electrically conductive interference elements can reach in the region of the contact elements from the side when contacting the component. In addition, the protective wall has a component-guiding effect which safely ensures the correct contacting of the desired contact points of the component. Furthermore, the embodiment of the contact module according to the invention allows the contact elements to be protected inside the contact space, so that damage to the contact elements is avoided in case of a faulty actuation of the contact module. The protective wall, which protrudes out from the contact side of the carrier, thus forms a simple technical measure which leads to significant advantages with regard to carrying out tactile contacting using the contact module.

According to another preferred embodiment of the invention, it is provided in particular that the protective wall is designed as a jacket wall which extends peripherally around the contact elements along the side. In this case, the protective wall extends in particular as a closed jacket wall around the contact elements around. The fact that the protective wall is designed as a jacket wall provides it with a high stability. In addition, it can be inexpensively designed and arranged on the carrier. In particular, the protective wall is formed integrally with the carrier in order to obtain a structurally simple and robust carrier component. The protective wall preferably forms, together with the carrier, an at least substantially continuous outer jacket wall surface of the contact module.

According to another preferred development, it is also provided that the carrier and/or the jacket wall are made of an electrically non-conductive material. As a result, a simple arrangement and attachment of the contact elements to the carrier is possible because it is possible to dispense with additional electrically-insulating measures. In particular, the carrier and the jacket wall are made of plastic. This makes it possible to realize a wide variety of different shapes and sizes of the contact module cost-effectively. According to an alternative embodiment of the invention, preferably only the carrier is preferably made of plastic, while the jacket wall is made of an electrically-conductive material, so that the jacket wall in particular forms one of the contact elements. This provides a highly integrated contact module. In this case, the jacket wall preferably has an electrically-insulating coating at least on the outside thereof in order to prevent electrical tactile contacting with adjacent electrically-conductive elements.

According to an advantageous embodiment of the invention, it is also preferably provided that the protective wall, at the end thereof facing away from the carrier, comprises a centering device for introducing the component into the contact space. By means of the centering device, the guiding of the component toward the contact elements is mechanically simplified, because in this way an assignment of the component to the contact elements in the contact space takes place mechanically.

Preferably, the centering device has at least one insertion bevel. This is expediently oriented in such a way that it has a radius, in particular a diameter, which tapers from the end of the protective wall in the direction of the carrier so that the centering device is present in the form of a centering ring in particular, with an inner insertion bevel, for example a conical insertion bevel.

According to another preferred embodiment of the invention, it is provided that the insertion bevel is formed integrally with the protective wall. This results in a compact unit that provides easy assembly and manufacture. Alternatively, the insertion bevel is preferably designed as a separate centering element and attached to the protective wall. As a result, the protective wall and insertion bevel can be made independently of each other and then connected together. This offers cost advantages, especially in the production of the protective wall itself. In particular, this ensures that the protective wall can also be formed integrally with the carrier without having to take account of undercuts in a demolding process.

According to another preferred embodiment of the invention, it is also provided that at least one of the contact elements is designed as an electrically-conductive contact ring which is assigned in particular to the end of the protective wall. As already mentioned above, the protective wall itself can form this contact element, for example. Alternatively, however, the contact ring is formed by a component which is made of an electrically-conductive material and which is separate from the protective wall. For example, by assigning the contact ring to the end of the protective wall, the contact ring can be used in particular to contact an annular contact point of a component, as can be found, for example, in some (electrical) energy storage media. For example, the contact ring is fixed to the electrically non-conductive protective wall, in particular glued, caulked or screwed, in which case preferably the remaining contact elements are designed as spring contact pins or other resilient contact elements whose free end and respective contact head lie in the contact space and protrude out over the contact ring —seen from the contact side—so that the free ends and contact heads can deflect inward until the contact ring makes is electrical tactile contact with the component. In addition, according to a further advantageous embodiment, it is provided that at least one of the contact elements is designed as a curved, preloaded leaf spring contact which extends in particular in the longitudinal extension of the contact module, in particular along the inside of the protective wall, and bulges inwardly, so that a lateral contact point of the component or the energy storage medium can be safely contacted.

Furthermore, it is preferably provided that the contact ring is slidably mounted on the inside of the protective wall. Thus, the contact ring can be moved along the protective wall on the inside thereof. Thus, the position of the contact ring is on the one hand adaptable to different components, and on the other it ensures that an electrical tactile contact is safely ensured both between the inner contact elements and between the contact ring and the component.

It is particularly preferable for the contact ring to be spring-mounted in the direction of the carrier. This means that at least one spring element is associated with the contact ring, the spring element counteracting the insertion of the contact ring into the contact space or in the direction of the carrier. Thus, the contact ring acts like a spring contact pin, which can safely compensate for differences in height of the contact points of the component to be tested. If the contact ring is present at the contact module, then the remaining contact element or elements is or are preferably arranged within the contact ring, i.e. within the inner diameter of the contact ring, so that the contact ring can safely be pushed past the module when the ring springs inward.

According to an advantageous embodiment of the invention, it is preferably provided that disposed in the carrier within the contact space is at least one spacer which projects from the contact side for limiting a penetration depth of the component into the contact space. The spacer thus limits the path along which a component can be moved into the contact space. As a result, the spacer acts as a kind of spring path limiter which in particular prevents over-stressing of the spring elements of the contact spring element and/or the spring-loaded contact ring.

The spacer is in particular formed integrally with the carrier so that it can be implemented inexpensively and robustly and in particular electrically non-conductively.

Furthermore, it is preferably provided that at least one control device with at least one electrical/electronic control component for operating the contact module is arranged on the connection side of the carrier. The control device is in particular electrically connected to the contact elements of the contact module in order to be able to apply an electrical voltage or an electrical current to the contact points so as to carry out a test or electrical processing, and/or in order to be able to detect a current or voltage in effect at the contact points of the component. The contact elements can also be designed or used to detect or check a temperature or mechanical values, such as compressive strength values of the component, for example. In other words, the contact module can not only be used to actively operate or test the component, but also to passively or actively record measurement results, which permits information to be provided about the robustness of the component, the age of the component, the operating state of the component or the like, for example. Alternatively or additionally, the control device preferably has an electrical interface, in particular in the form of one or more plug contacts, which form an electrical connection to a higher-level test device with which the contact module can be connected. In particular, the electrical interface is designed such that the interface automatically establishes contact with the test device when the contact module is installed, for example in a carrier system plate of the contact system. The plug contacts are aligned in particular in the longitudinal direction or longitudinal extension of the contact module to establish a plug connection when installing the contact module or when inserting the contact module in an opening of the carrier system plate in the direction of movement or in the longitudinal direction of the contact module. Particularly preferably, the control device has at least one printed circuit board which has a plurality of contact points which is connectable/connected to the contact elements. By the fact that the control device is assigned to the connection side of the carrier in particular or is disposed on the connection side of the carrier, a simple and secure electrical connection and/or interconnection of the contact elements with each other is possible here. For this purpose, the printed circuit board comprises in particular one or more electrical conducting paths, which are electrically connected to the contact elements on the connection side, in particular tactile-contacted, welded, soldered or frictionally connected.

According to a preferred embodiment of the invention, it is provided that at least one coolant channel, in particular a cooling air channel, is formed or disposed in and/or on the contact module, in particular in and/or on the carrier and/or the protective wall. A coolant can be passed through the coolant channel, the coolant being made available for example by the test device or processing pre-device. As a result, the coolant channel can be integrated into the cooling circuit of the contact system, for example. The coolant channel is preferably formed in the carrier and/or the protective wall by one or more depressions, openings, apertures, perforations or the like. Due to the coolant flowing through the coolant channel, the carrier and thus the components disposed on the carrier are cooled and heat is dissipated, as a result of which the electrical/electronic components of the contact module are reliably protected against overheating, in particular during a forming process. Particularly preferably, the coolant channel, or a further coolant channel, opens into the contact space so that the component to be contacted is also flowed past or around by the coolant. In particular, it is provided that the contact system comprises a cooling air device to which the coolant channel can be connected so that the cooling air provided by the cooling air device flows into the contact space flows through the coolant channel and there acts on the tactile-contacted component and in particular flows along said component in order to dissipate heat by convection. As a result, the component to be contacted, in particular the energy storage medium, is cooled during the forming process.

The preferred control component of the control device for operating the contact module is designed in particular as a microprocessor and/or integrated circuit here, so that predetermined testing or processing operations can be performed by the contact module itself. This has the advantage, for example, in that the respective contact module does not answer a central control unit with raw data which still has to be evaluated, but that a central control unit receives already evaluated sensor data. In particular, the control component is designed to convert detected analog signals into digital signals and optionally to process the digital signals (beforehand).

In addition, it is preferably provided that the carrier and/or the protective wall in particular have on the outer jacket sides thereof means for releasably locking in an opening of a carrier system plate. The means allows the locking of the contact module in the opening, in particular without tools. As a result, a simple mounting of the contact module in a carrier system plate in which a plurality of such contact modules can be disposed, is ensured. Preferably, the means are designed as locking means, clamping means or pressing means which form in the opening a frictional connection and/or a positive connection with the carrier system plate, by which the contact module is securely held in the opening. For example, for this purpose the outside of the jacket wall has one or more radially projecting compression rings which permit a non-destructive attachment and detachment of the contact module to the carrier system plate. Also, the means may have one or more elastically displaceable locking lugs, which cooperate with corresponding locking openings of the carrier system plate for positive locking. Of course, the locking lugs can also be formed on the carrier system plate and the locking openings can be formed on the contact module. In any case, a simple exchange of the respective contact module is possible, whereby a test system or processing system, in particular an energy storage medium forming system with a corresponding carrier system plate, for example, is easily and quickly adaptable to different components.

The contact system according to the invention with the features of claim 15 is characterized in that the respective contact module is designed according to the invention. This results in the advantages already mentioned above.

In the following, the invention will be explained in more detail with reference to the illustration. For this

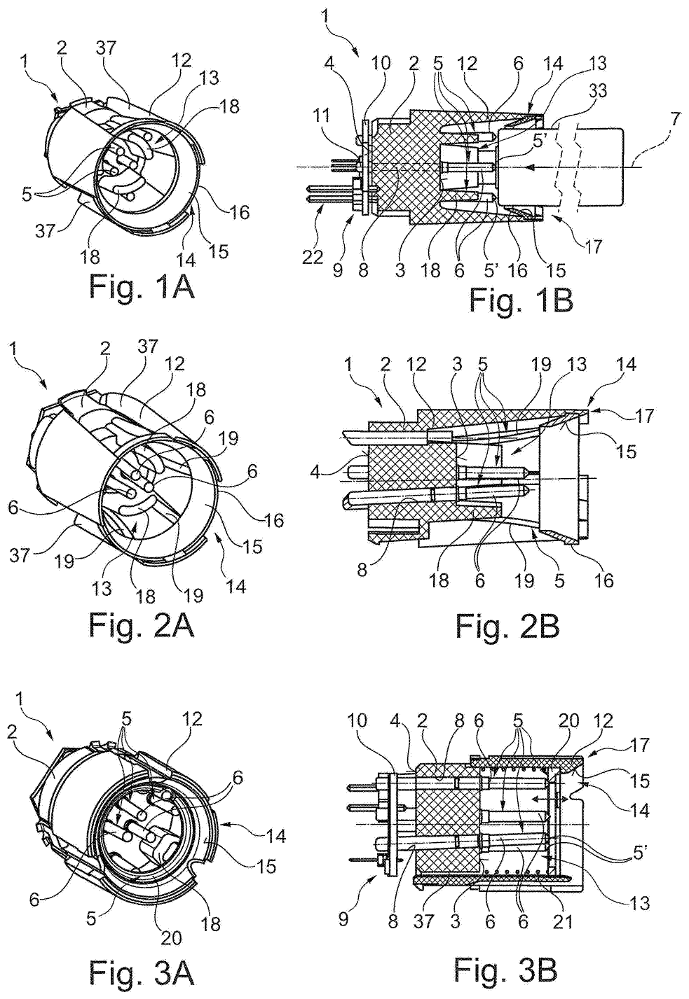

FIGS. 1A and 1B show a first exemplary embodiment of an advantageous contact module,

FIGS. 2A and 2B show a second exemplary embodiment of the advantageous contact module,

FIGS. 3A and 3B show a third exemplary embodiment of the advantageous contact module,

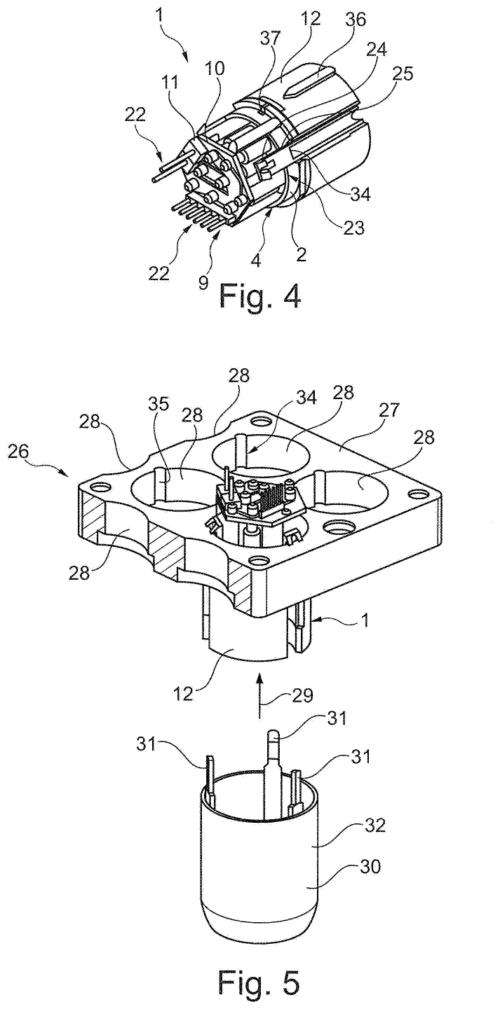

FIG. 4 shows a perspective rear view of the advantageous contact module and

FIG. 5 shows an advantageous contact system with the advantageous contact module.

FIGS. 1 to 3 show three different embodiments of an advantageous contact module 1, each in a perspective view and in a longitudinal sectional view. The basic structure will first be explained with reference to the contact module 1 shown in FIGS. 1A and 1B.

FIG. 1A shows the contact module according to the first exemplary embodiment in a perspective view and in FIG. 1B in a longitudinal sectional view. The contact module 1 has a substantially cylindrical basic structure and is configured to electrically contact a component at a plurality of contact locations. In the present case, the component is an energy storage medium 33 in which both the positive pole and the negative pole are located on an end face of the energy storage medium 33 so that they can be tactile-contacted simultaneously by the contact module 1 when the energy storage medium 33 is introduced to the contact module 1 or the contact module 1 is introduced to the energy storage medium 33.

The contact module 1 has a block or carrier 2 which is made of an electrically non-conductive material. The carrier 2 has an essentially circular disc-shaped basic structure, with a contact side 3 which can be assigned to the component, and a connection side facing away from the contact side 3. Contact side 3 and connection side 4 form the end faces of the carrier 2.

On the carrier 2, a plurality of contact elements 5 is held in the present case which are formed according to the present embodiment as spring contact pins 6. The spring contact pins 6 may be held parallel to a longitudinal axis 7 of the contact module 1 or inclined at a predetermined angle to the carrier 2. The spring contact pins 6 penetrate the carrier 2 by being held in passage openings 8 of the carrier 2. Thus, the contact pins 6 protrude from both the contact side 3 and the connection side 4. On the contact side 3, the spring contact pins 6 have spring-mounted contact heads 5′ which can be compressed inward in the direction of the carrier 2. This ensures that height differences in the contact points of the component are compensated by the spring contact pins 6 in the event tactile contact is made with the component. At the connection side 4, the spring contact pins 6 and the contact elements 5 are connected to a control device 9. This device comprises a circuit board 10 disposed on the connection side 4 through which the present contact elements 5 are passed. In this case, the contact elements 5 are electrically connected to conducting paths or contact paths of the printed circuit board 10 and thereby electrically interconnected with each other and in particular with an electrical and/or electronic control component 11 which is, for example, a microprocessor or an integrated circuit. The control device 9 is in particular designed to control the contact elements 5 for energy transmission and/or signal transmission, for example in order to carry out tests on or a forming process of the component. For this purpose, the control device 9 is designed for example to act on the contact elements 5 with a predetermined current and/or a predetermined voltage, respectively, wherein the current can be both impressed, in particular as a charging current, or discharged, in particular a discharging current. In particular, applying and/or detecting a voltage by means of the contact elements 5 serves to carry out a measurement or an electrical test. Also, the contact elements 5 can be used by the control device 9 as simple measuring sensors. Also, other sensors may be disposed on the carrier 2, such as temperature sensors or the like. The control component 11 controls or regulates the performance of a test or electrical processing, in particular the formation of the energy storage medium, and in particular sensor data or measurement data acquired by the component 11 are digitized and/or pre-evaluated and then forwarded to a central control unit for further use. For this purpose, the control component 11 preferably has an analog-to-digital converter which digitizes the sensor data or values acquired in analog fashion, optionally preprocessing them and forwarding them. As a result, the contact module 1 becomes an “intelligent” contact module which can send already pre-processed data as digitized data to a central unit, which allows a fast and simple evaluation of data, especially if a plurality of such contact modules 1 is used in a contact system, as explained below.

A protective wall 12 also extends from the carrier 2, the wall projecting from the contact side 3 such that it projects beyond the contact elements 5 in the direction of the longitudinal axis 7. According to the first embodiment of FIGS. 1A and 1B, it is provided that the protective wall 12 is not formed continuously, but interrupted in the circumferential direction. As a result, the weight of the protective wall 12 is kept low. At the same time, however, the protective wall 12 ensures that the contact elements 5 are securely protected in the contact space 13 formed by the protective wall 12. In particular, the protective wall 12 prevents the contact elements 5 from coming into contact with electrically-conductive elements in the vicinity of the contact module 1, so that an undesirable short circuit or undesired measurement results are reliably prevented. In the present case, the protective wall 12 has three protective wall parts, which, viewed in the circumferential direction, are arranged at a distance from each other. In contrast to the illustrated embodiment, however, the protective wall 12 may also have more or fewer protective wall parts. The protective wall 12 is formed integrally with the carrier 2 according to the present embodiment, as can be seen in particular in FIG. 1B.

Furthermore, the protective wall 12 has an inner diameter which tapers in the direction of the carrier 2, so that the protective wall 12 simultaneously forms a centering device 14 for a component introduced into the contact space 13. Alternatively or additionally, the centering device 14 is formed by an additional insertion bevel 15, which is formed by a separate centering element 16 on the end 17 of the protective wall 12 facing away from the carrier 2. In the present case, the centering element 16 is clipped in a form-fitting manner into the protective wall 12 at the end 17 as a funnel-shaped element. For this purpose, each of the protective wall elements comprise radial openings at the end 17 on the inside into which corresponding projections of the centering element 16 can be inserted. The protective wall parts are designed at least partially to be elastically deformable such that they can be pulled apart to expand the diameter thereof. As a result, a simple insertion and clipping of the element 16 or the insertion bevel 15 of the centering device 14 is ensured. The centering device 14 is thus held interchangeably on the contact module 1, so that by inserting different centering elements 16 into the contact module 1, the module is easily adaptable to different components. The centering bevel or insertion bevel 15 ensures that the respective component is exactly guided to the contact elements 5 in such a way that a secure electrical tactile contacting of its contact points takes place.

The carrier 2 also has one or more spacers 18 projecting from the contact side 3 of the carrier 2. The spacers 18 are shorter than the contact elements 5 in the unactuated state as seen in the direction of the longitudinal axis 7. The spacers 18 thus act as limiters of the compression depth of the spring contact pins 6 or the insertion depth of a component into the contact space 13. As a result, a mechanical overstressing of the contact elements 5, in particular when performing a test or a processing operation on a component is reliably prevented.

While in FIG. 1B, the contact module 1 is aligned horizontally in the longitudinal extent in accordance with the longitudinal axis 7, the contact module 1 is preferably oriented vertically in such a manner that the contact side 3 faces downwards and the connection side 4 faces upward. Thus, the contact module 1 can be placed from above onto the component to be tactile-contacted or the component to be contacted can be inserted from below into the contact space 13. This has the advantage that the dead weight of the component to be contacted can be used to remove the component from the contact module by simply lifting the contact module 1 or moving a carrier which holds the component downward.

Thus, FIGS. 2A and 2B show a second embodiment of the contact module 1 in a perspective view in a longitudinal sectional view, wherein elements already known from FIG. 1 are provided with the same reference signs and reference as such is made to the above description. In the following, only the differences will be explained.

In contrast to the previous embodiment, the contact module 1 comprises leaf spring contacts 19 as additional or alternative contact elements 5, the leaf spring contacts extending in curved fashion from the contact side 3 to the end 17 at least up to the centering element 16 and thereby bulging in the direction of the contact space 13 so that when a component is introduced into the contact space 13, the leaf spring contacts 19 sit against an end face of the component, in particular a front edge in the transition from an end face to an outer jacket wall of the component, and exert a biasing force due to the curved design thereof to ensure secure tactile contacting against the side of the component. The leaf spring contacts 19 are in particular designed such that the cylindrical jacket surface or outer jacket wall of the component is not enclosed, so that no jamming occurs which could hinder the removal of the component by its own weight from the contact space 13.

Thus, FIGS. 3A and 3B show a further embodiment of the contact module 1 in a perspective view in a longitudinal sectional view, wherein elements already known from the preceding figures are provided with the same reference signs and reference as such is made to the above description. In the following, it is the differences which are substantially covered.

In contrast to the first exemplary embodiment, the contact module 1 now has an additional contact element 5 in the form of an electrically-conductive contact ring 20. The contact ring 20 has an outer diameter which corresponds nearly with the inner diameter of the protective wall 12, so that the contact ring 20 is mounted on the inside of the protective wall 12 and can move smoothly in the direction of the longitudinal axis 7. In this case, the protective wall 12 preferably has no diameter tapering or centering function in the displacement path or region of the contact ring 20, as best shown in FIG. 3B. The centering device 14 in this case is preferably formed at the free end 17 of the protective wall 12, where in this case the centering element 16 is preferably integrally formed together with the protective wall 12 or is inserted as a separate component. The centering element 16 projects radially inward beyond the contact ring 5, so that it is held captive in the contact space 13. In this case, the protective wall 12 is preferably formed separately from the carrier 2 and fastened to it in a form-fitting and/or material-locking manner. An electrically conductive spring element 21, for example a coil spring and/or a spring contact pin, is held pre-stressed between the contact side 3 and the contact ring 5, preferably at least one and in particular for signal or power lines, so that the spring element biases the contact ring 20 in the direction of the centering element 16. Radially inside the contact ring 20 are the other contact elements 5 and spring contact pins 6. If, now, the contact module 1 is guided toward a component or the component toward the contact module 1, so that the component penetrates into the contact space 13, both the spring contact pins 6 and the contact ring 20 are tactile contacted and can be compressed to compensate for height differences, so that a secure electrical contact of the component is securely ensured by all contact rings 5.

FIG. 4 shows a perspective rear view of the contact module 1, here according to the third exemplary embodiment. In contrast to the first and the second embodiment, the protective wall 12 according to the third embodiment comprises a continuous protective wall 12 which is thus closed on the periphery or at least substantially closed. This provides an advantageous sliding mounting for the contact ring 20. As already mentioned above, the control device 9 with the printed circuit board 10 is disposed on the connection side 4 of the carrier 2. On the side facing away from the carrier 2, plug contacts 22 are also preferably formed on the printed circuit board 10, the contacts enabling a simple contacting of a test device or processing device. This will be discussed in more detail later with reference to FIG. 5. The fact that the control device 9 is disposed on the connection side 4, it is thermally and mechanically decoupled substantially from the rest of the contact module 1, so that solder joints and connection points are less loaded at the control device 9 during operation.

In addition, it can be seen in particular in FIG. 4 that the contact module 1 has means 23 for releasably locking the contact module 1 on a carrier system plate, as shown by way of example in FIG. 5. In the present embodiment, the means 23 are provided as locking lugs 24 arranged or formed on the protective wall 12 which are arranged at the end of elastically inwardly displaceable locking tongues 25 of the protective wall 12. In this case, the locking lugs 24 are assigned to the connection side 4 at the height of the carrier 2 and are radially spaced relative to the carrier 2 so that they can swing radially inward in the direction of the carrier 2.

FIG. 5 shows an exemplary contact system 26, which has a carrier system plate 27 in which a plurality of openings 28 is formed or arranged uniformly, in particular in the form of a matrix, at a distance from each other. In the present case, the openings 28 are formed as penetrations. If now the contact module 1 is inserted axially into one of the openings 28, then it can be pushed in far enough for the printed circuit board 10 or the control device 9 to protrude from the carrier system plate 27. The locking lugs 24 are displaced radially inwardly when inserted into the opening according to arrow 29 in FIG. 5 and due to their elasticity or residual stress after reaching through the opening 28 snap radially outward, thereby engaging the carrier system plate 27 positively and thereby locking the contact module 1 securely on the carrier system plate 27. By means of a simply designed tool 30, which is shown in FIG. 5, the contact module 1 can be easily detached from the carrier system plate 27 at any time. For this purpose, for each of the locking lugs 24 the tool 30 has a respective release slide 31 which is arranged on a sleeve-shaped base body 32. The sleeve-shaped base body 32 is designed to be slid onto the contact module 1 from the contact side. The release slides are pushed onto the tongues 25, which have an actuating bevel 34. As soon as the release slides 31 strike the actuating bevel 34, the locking tongues 25 are displaced radially inwardly together with the locking lugs 24 so that the locking connection to the carrier system plate 27 is released. Subsequently, the contact module 1 can be easily removed from the carrier system plate and replaced by another contact module 1 or a same, but newer contact module 1.

In order to ensure correct alignment of the respective contact module 1 in the carrier system plate 27, the carrier system plate 27 and the respective contact module 1 each form a form-fitting anti-rotation device 34. For this purpose, the openings 28 and the contact module 1 have an internal and external contour which differs from a circle, wherein the inner contour of the respective opening 28 is designed to correspond to the outer contour of the contact modules 1. In the present case this is achieved in that each opening 28 has a radial groove 35 on the inner wall thereof which extends axially or in the insertion direction of the contact module 1. The contact modules 1 expediently have a radial projection 36 which can be inserted into the radial opening 35. When mounting the respective contact module 1 on the carrier system plate 27, the respective contact module 1 can only be inserted into the respective opening 28 when the radial opening 35 and the radial projection 36 are aligned with each other. As a result, incorrect assembly or misalignment of the contact modules 1 on the carrier system plate 27 is reliably prevented.

The advantageous embodiment of the contact module 1 and the contact system 26 thus ensures a simple replacement and simple assembly of a carrier system plate 27, using the same and/or different contact modules 1. The contact modules 1 themselves also allow error-free operation by the contact elements 5 securely lying in the contact space 13 and being protected by the protective wall 12. By arranging a plurality of contact modules 1 on the carrier system plate 27, a plurality of components, in particular energy storage media 33, can be contacted electrically at the same time by a corresponding displacement of the carrier system plate 27. In particular, when the components are designed as energy storage media 33, as already mentioned above, the energy storage medium for the so-called forming process is electrically contacted by means of the contact modules 1, for example, and the formation of the energy storage media is performed.

In the case of energy storage media in particular, the positive pole and negative pole are simultaneously touched by the respective contact module 1, which ensures a simple movement mechanism for contacting the components as well as a simple wiring and electrical system of the respective contact module 1 and contact system 26. As already mentioned above, the respective component and/or the respective contact module 1 or the carrier system plate 27 can be moved in order to produce the tactile contacting. In particular, it is provided that the component, in particular the energy storage medium 33, is moved to the contact module 1. Particularly preferably, a plurality of components is disposed on a common holder, and by moving the holder, the components are simultaneously guided to the contact modules of the contact system 26. The advantage of moving the component is, in particular, that the less complex system is moved and that the more complex contact systems 26, due to the wiring and necessary electrical/electronic system, does not have to be moved. In addition, the force of the weight of the components or energy storage medium 33 is advantageously utilized to easily remove the components from the respective contact module 1 when the components or the holder are moved down. During the testing process, the components can be cooled laterally or from the side facing away from the respective contact module 1. In addition to spring contact pins as contact elements 5, bending contacts, in particular buckling contact elements, can also be used. In particular, it is possible to use contact elements 5 which produce a contact force transverse to the axial load during the tactile contacting, whereby the respective contact head is displaced laterally along the respective contact point of the component so that the surface of the contact point is scratched and thereby secure electrical contact is made. This is achieved for example by inclined spring contact pins 6, as shown for example in FIGS. 1A and 3A. The penetration of a passive surface of a negative or positive pole of an energy storage medium is made possible by this principle, the reduction of an axial contact force of the respective contact element and thus the mechanical stress of the energy storage. The fact that the contact elements 5 are held in the carrier 2, which in particular is electrically non-conductive, additional electrically insulating means to avoid short circuits are not necessary.

The carrier 2 and/or the protective wall 12 may themselves be formed as sub-modules and be separately exchangeable. Also, the control device 9 or parts thereof can be designed as interchangeable sub-modules. The different sub-modules may provide different functions such as fixing/locking, centering, sliding bearings, stiffness, heat conduction, thermal insulation, electrical conduction, electrical insulation or the like. Individual parts of the carrier 2 may be made of different materials specialized in their respective sub-function. Preferably, the carrier 2 and the protective wall 12 are made of an electrically insulating plastic. In addition to the aforementioned object, the control device 9 can also have further means for carrying out further tasks, such as temperature, shock, humidity and/or gas sensors, signal amplification for detecting the cell voltage and/or contact resistances, an analog-digital converter for signal processing, a data memory in which, for example, a serial number of the contact module 1 is deposited/stored, a counter for detecting a clock time, contacting cycles or the like, a data memory for detecting and storing critical limits, certain sensor data and/or maintenance intervals, a microcontroller for self-monitoring and/or a bus communication system for data routing.

In addition, the shape of the contact module 1 has the advantage that, on the one hand, standardized electrical mechanical interfaces can be used, and, on the other hand, a high degree of flexibility in terms of freedom of design is provided. Thus, the contact system 26 advantageously has differently designed contact modules 1 which, however, are similar in terms of the formation of the connection side 4 and the means 23 for locking the respective contact module 1 in the carrier system plate 27. This allows contact modules 1 with different functions to be disposed in the same carrier system plate 27 and for the modules to be interchanged with one another. This results in a high degree of flexibility in the assembly of the carrier system plate 27 and in the application of the contact system 26. If the connection side 4 in each case has the same configuration with respect to the plug contacts 22, this ensures a simple connection and replacement of contact modules 1 designed differently on the contact side 3. The different contact modules 1 shown in FIGS. 1 to 3 are thus of identical design, in particular with respect to the connection side 4 and the shape of the carrier 2, the protective wall 12 and in particular also the locking means 23 and differ in particular only in the arrangements and design of the contact elements 5 in the contact space 13.

Optionally, the carrier 2 is provided with at least one coolant channel 37 which, for example as shown in FIGS. 3B and 4, is designed as a cooling air channel and opens into the contact space 13. An inlet opening of the coolant channel 37 is formed on the connection side 4 of the carrier 2. Cooling air, which is provided by a contact system 26, in particular by a cooling air device of the contact system 26, can be guided into the contact space 13 through the coolant channel 37. As a result, on the one hand, the contact module 1 itself and the electrical/electronic elements arranged thereon are cooled, and on the other hand cooling air flows around the energy storage medium 33 in particular during the forming process, thereby cooling the medium. In the simplest case, the cooling air device acts on the entire upper side of the carrier system plate 27 so that the cooling air passes through the coolant channel 37 of the respective contact module 1 into the respective contact space 13 through the free inlet opening of the coolant channel 37 of the contact modules 1. Of course, the contact modules 1 can also have more than just one coolant channel. It is also conceivable to additionally or alternatively design one or more coolant channels 37 in the protective wall 12, as shown for example in FIGS. 1A and 2A. Coolant channels 37 are designed there in the form of wall openings through the segmented design of the protective wall 12. Cooling air can flow into and out of the contact space 13 through the free space between two adjacent protective wall segments.

1. A contact module for making electrical tactile contact with a component, the contact module comprising: carrier having a carrier which has a contact side assignable to the component and a connection side facing away from the contact side, and at least two electrically conductive contact elements, at least one of the electrically conductive contact elements being a spring contact pin with a spring-loaded contact head, wherein free ends of the at least two contact elements protrude from the contact side of the carrier for making tactile contact with the component, wherein at least one protective wall is disposed on the contact side of the carrier, the at least one protective wall forming at least one contact space in which the free ends of the contact elements are disposed.

2. The contact module according to claim 1, wherein the protective wall is a jacket wall which extends peripherally around the contact elements along the side.

3. The contact module according to claim 1, wherein at least one of the carrier and the protective wall is made of an electrically non-conductive material.

4. The contact module according to claim 1, wherein the protective wall at an end thereof facing away from the carrier comprises a centering device for centrally introducing the component into the contact space.

5. The contact module according to claim 4, wherein the centering device comprises at least one insertion bevel.

6. The contact module according to claim 5, wherein the insertion bevel is formed integrally with the protective wall or is fixed to the protective wall as a separate centering element.

7. The contact module according to claim 1, wherein at least one of the contact elements is a leaf spring contact or an electrically conductive contact ring.

8. The contact module according to claim 1, wherein at least one of the contact elements is a contact ring, the contact ring slidably mounted on an inside of the protective wall.

9. The contact module according to claim 1, wherein at least one of the contact elements is a contact ring, the contact ring mounted spring-loadable in the direction of the carrier.

10. The contact module according to claim 1, further comprising at least one spacer disposed in the carrier within the contact space which projects from the contact side for limiting a penetration depth of the component into the contact space.

11. The contact module according to claim 10, wherein the at least one spacer is formed integrally with the carrier.

12. The contact module according to claim 1, further comprising at least one control device disposed on the connection side of the carrier, the at least one control device having at least one electrical/electronic control component for operating the contact module and/or an electrical interface.

13. The contact module according to claim 1, further comprising at least one coolant channel formed in and/or on the contact module, wherein the at least one coolant channel opens into the contact space.

14. The contact module according to claim 1, further comprising means for releasably locking in an opening of a carrier system plate, the means for releasably locking located on an outside jacket wall of the carrier and/or the protective wall.

15. A contact system for making electrical tactile contact with a plurality of identically formed components, the contact system comprising:
at least one carrier system plate with a plurality of openings; and
a plurality of contact modules for making electrical tactile contact with the components,
wherein in one or more of the openings one of the contact modules is releasably locked or lockable,
wherein each of the contact modules includes a carrier having a contact side assignable to one of the components and a connection side facing away from the contact side, and at least two electrically conductive contact elements, at least one of the electrically conductive contact elements being a spring contact pin with a spring-loaded contact head, wherein free ends of the at least two contact elements protrude from the contact side of the carrier for making tactile contact with the component, wherein at least one protective wall is disposed on the contact side of the carrier, the at least one protective wall forming at least one contact space in which the free ends of the contact elements are disposed.

16. The contact module according to claim 3, wherein at least one of the carrier and the protective wall is made of plastic.

17. The contact module according to claim 13, wherein the at least one coolant channel is a cooling air channel.
